(19) United States
(12) Patent Application Publication
(10) Pub. No.: US 2014/0017615 A1
(43) Pub. Date: Jan. 16, 2014

(54) APPARATUS AND METHOD FOR RESIST COATING AND DEVELOPING

(71) Applicant: Ching-Yu Chang, Yuansun Village (TW)

(72) Inventor: Ching-Yu Chang, Yuansun Village (TW)

(73) Assignee: TAIWAN SEMICONDUCTOR MANUFACTURING COMPANY, LTD., Hsin-Chu (TW)

(21) Appl. No.: 13/546,125

(22) Filed: Jul. 11, 2012

(51) Int. Cl. B05C 13/02; G03F 7/20

(52) U.S. Cl. 430/325; 118/500

(57) ABSTRACT

An apparatus includes a chuck, a first drain cup and second drain cup with two separately drain lines connected to each drain cup. The second drain cup is integrated with the first drain cup and located on top of the first drain cup. The different based chemical wastes can be collected into the separated drain cups and furthermore into the different drain lines and waste tanks. Accordingly, different based photo resists and developers can be used at the same apparatus by adjusting the chuck position to save the coating and develop tool and clean room space and furthermore the production cost.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs and, for these advances to be realized, similar developments in IC processing and manufacturing are needed.

For example, lithography processes often use techniques such as bottom anti-reflectance coating (BARC) resists and top anti-reflectance coating (TARC) resists, to improve resist pattern profiles and improve process margin with the shrinking of the feature size. However, the BARC and TARC resist are different based chemicals compared to a regular photo resist. In another example, an organic solvent based developer is applied for a negative tone developing process, in which the organic solvent developer is different than a positive tone developer. Therefore, more tools and clean room space are needed in order to implement the BARC and TARC resist processes, and the negative tone developer, and thus a cost for fabricating an IC circuit is increased.

Accordingly, what are needed are an apparatus and a method that address the above issues.

### BRIEF DESCRIPTION OF THE DRAWINGS

The present disclosure is best understood from the following detailed description when read with accompanying figures. It is emphasized that, in accordance with the standard practice in the industry, various features are not drawn to scale and are used for illustration purpose only. In fact, the dimension of the various features may be arbitrarily increased or reduced for clarity of discussion.

FIG. 1 is a flow chart of a method for forming a resist pattern according to one or more embodiments of the present disclosure.

FIGS. 2-6 are diagrammatic cross-sectional side views of forming a resist pattern according to one or more embodiments of the present disclosure.

FIG. 7 illustrates a diagrammatic cross-sectional side view of an apparatus with a single drain cup according to one or more embodiments of the present disclosure.

FIGS. 8-9 illustrate diagrammatic cross-sectional side views of an apparatus with more than one drain cups according to one or more embodiments of the present disclosure.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

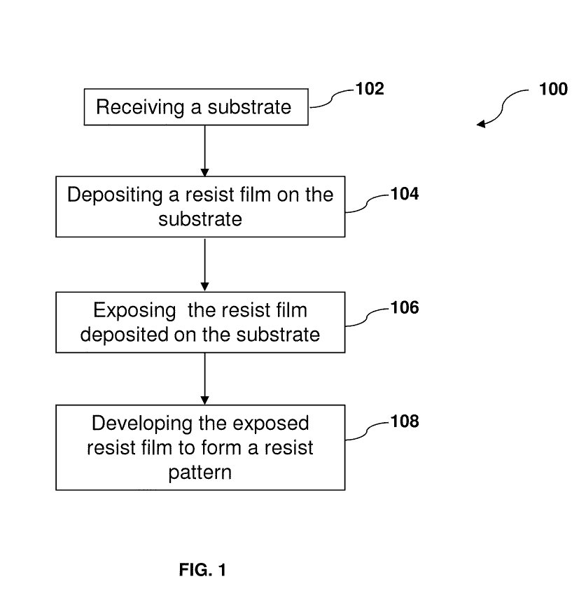

Referring to FIG. 1, a flow chart of a method 100 is an example of forming a resist pattern on a substrate according to one or more embodiments of the present disclosure. The method 100 begins at step 102 by providing or receiving a substrate. The method 100 proceeds to step 104 by depositing a resist film on the substrate, for example, by a spin-on coating process. In the present disclosure, a resist is also referred to as a photo resist. The step 104 may include a dehydration process to enhance an adhesion of the resist film to the substrate before applying the resist on the substrate. The dehydration process includes baking the substrate at a high temperature for a duration of time, or applying a chemical such as hexamethyldisilizane (HMDS) to the substrate. The step 104 may also includes a soft bake (SB) process to increase a mechanical strength of the resist film. After step 104, the method 100 proceeds to step 106 for exposing the resist film deposited on the substrate by an exposing tool to form a latent image pattern on the resist film. The exposing tool may include an optical exposing tool such as a I-line (365 nm) tool, a deep ultraviolet (DUV) tool, an extreme ultraviolet (EUV) tool, or an X-ray exposing tool, or a charged particle tool such as an electron beam writer. The method 100 proceeds to step 108 by developing the exposed resist film to form a resist pattern on the substrate on a developing track. The step 108 may include a post exposure rinse, a post exposure bake (PEB), a developer rinse, a post develop bake (PDB), or combination thereof. Additional steps can be provided before, during, and after the method 100, and some the steps described can be replaced, eliminated, or moved around for additional embodiments of the method 100.

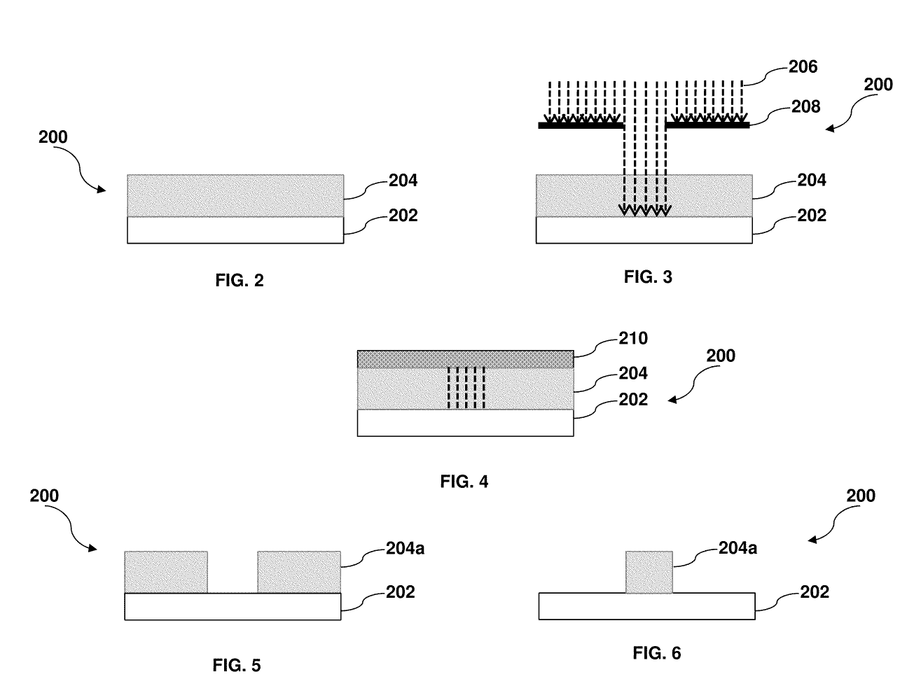

Referring now to FIGS. 2-6, diagrammatic cross-sectional side views of forming a resist pattern of a device 200 by the method 100 is illustrated according to one or more embodiments of the present disclosure. The resist pattern of the device 200 includes a substrate 202 and a resist film 204 deposited on the substrate 202. However, other configurations and inclusion or omission of the device may be possible. In the present embodiments, the substrate 202 may include a wafer and a plurality of conductive and non-conductive thin films. The wafer is a semiconductor substrate including silicon (in other words, a silicon wafer). Alternatively or additionally, the wafer includes another elementary semiconductor, such as germanium; a compound semiconductor including silicon carbide, gallium arsenic, gallium phosphide, indium phosphide, indium arsenide, and/or indium antimonide; an alloy semiconductor including SiGe, GaAsP, AlinAs, AlGaAs, GaInAs, GaInP, and/or GaInAsP. In yet another alternative, the wafer is a semiconductor on insulator (SOI). A plurality of conductive and non-conductive thin films may comprise an insulator or a conductive material. For example, the conductive material comprises a metal such as aluminum (Al), Copper (Cu), tungsten (W), nickel (Ni), titanium (Ti), gold (Au), and platinum (Pt) and, thereof an alloy of the metals. The insulator material may include silicon oxide and silicon nitride. The resist film 204 may include a positive tone resist or a negative tone resist. The resist film 204 also includes a single resist film or a multiple layer resist film.

As shown in FIG. 3, the resist film 204 deposited on the substrate 202 is exposed, for example, by light 206 generated by an optical tool is projected on a mask 208 and some of the light 206 is blocked by the mask 208. Some of the light 206 passing the mask 208 is projected on the resist film 204 and reacts with a photo sensitive chemical in the resist film 204 and form a latten image. For example, the photo sensitive chemical is a photo acid generator (PAG) in a DUV resist. The PAG releases an acid under a radiation of the light 206 and forms the latten image. The light 206 includes I-line light, DUV light, EUV light, or X-ray light. The mask 208 blocks some of the light 206 and transfers a pattern of an IC design layout to the resist film 204. The mask 208 includes a binary mask (BIM) or a phase shift mask (PSM). The phase shift mask (PSM) may be an alternative phase shift mask (alt. PSM) or an attenuated phase shift mask (att. PSM). In the present disclosure, a mask is also referred to as a photomask or a reticle.

As shown in FIG. 4, a developer 210 is applied to the exposed resist film 204 deposited on the substrate 202 for developing a resist pattern. The PAG in the resist film 204 releases the acid under the radiation of the light 206 and the acid promotes a chemical amplify reaction (CAR) in an exposed area during the PEB process. Because of the chemical amplifies reaction (CAR), a polarity of the resist in the exposed area change from the hydrophobic polarity to the hydrophilic polarity. In the depicted embodiment, the final resist pattern depends on a developer tone. For example, if the developer 210 is a positive tone developer (PTD), such as hydrophilic tetramethylammonium hydroxide (TMAH), applied to the exposed resist film 204, the exposed portion (hydrophilic) of the resist film 204 are dissolved by the hydrophilic developer TMAH during the developing process and the unexposed portions (hydrophobic portions) of the resist film 204 remain to form a patterned resist film 204a, providing the final resist pattern shown in FIG. 5. In another example, if the developer 210 is a negative tone developer (NTD) such as a hydrophobic organic solvent applied to the exposed film 204, the unexposed portions (hydrophobic portions) of the resist film 204 are dissolved by the hydrophobic organic solvent and the exposed portions (hydrophilic portions) of the resist film 204 remain after the developing process to form a patterned resist film 204b, providing the final resist pattern shown in FIG. 6.

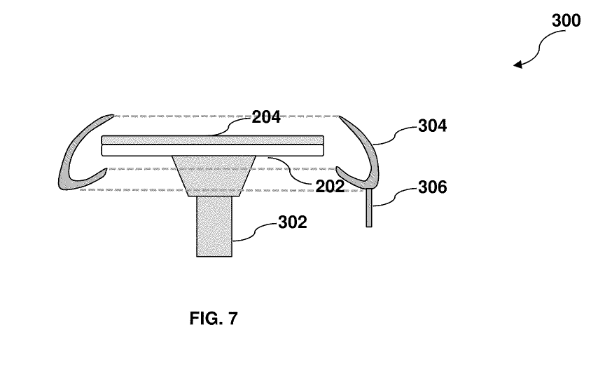

Referring now to FIG. 7, a diagrammatic cross-sectional side view of a track cup 300 is illustrated according to one or more embodiments of the present disclosure. The track cup 300 includes a chuck 302, a drain cup 304, and a drain line 306. The track cup 300 is connected to a vacuum system, a liquid delivery system, a rotation system, a wafer transfer system, a wafer loading/unloading system, an exhaust system, and a waste drain system. However, other configurations and inclusion or omission of devices may be possible. The track cup 300 is configured to provide a controllable environment for depositing the resist film 204 on the substrate 202 (scribed at step 104 of the method 100 shown in FIG. 1), developing the exposed resist film 204 deposited on the substrate 202 (described at step 108 of the method 100 shown in FIG. 1), or both. When the substrate 202 proceeds to step 104 of the method 100 for depositing the resist film 204 on the substrate 202, the wafer substrate 202 is first transferred to the chuck 302 by the substrate loading and unloading system and secured on the chuck 302 by the vacuum system. Then a resist material is dispensed on the substrate 202 by the liquid delivery system to form the resist film 204. During the dispensing, the substrate 202 is rotated in a high speed with the chuck 302 driven by the rotation system. During the high speed rotation, extra resist is spin off the surface of the substrate 202 and some of solvents are evaporated from the resist, eventually, the resist film 204 is deposited on the substrate 202 with a thickness of the resist film 204 ranging from several hundred angstrom (A) to hundred micrometer (um) depending on the resists and the spin speed. The exhaust system of the drain cup 304 and the drain line 306 of the track cup 300 provide a controllable environment to prevent resist material waste bouncing back from a side wall of the drain cup 304 to reduce a defect in the resist film 204. During the high speed rotation of the chuck 302, the extra resist is spin off from the surface of the substrate 202, is collected at the bottom of the drain cup 304, and is guided into the drain line 306 connected to a waste tank.

In the present disclosure, the similar track cup configuration 300 is also used for developing the exposed photo resist film 204 to form the resist pattern on the substrate 202 as shown in FIG. 4. After the resist film 204 is exposed and the post exposure baking (PEB) is performed, the substrate 202 deposited with the resist film 204 is transferred to the chuck 302 of the track cup 300 as shown for developing. First the developer 210 is dispensed on the resist film 204 by the liquid delivery system, and then the developer 210 is set on the wafer to allow the developer 210 to dissolve the unwanted photo resist. Finally a rinse solution is given when the chuck is in rotation to wash away the resist residue and the resist pattern is formed on the substrate. During the rotation of the chuck 302, the extra developer 210 and the final rinse solution are spin off from the surface of the resist film 204 deposited on the substrate 202, are collected at the bottom of the drain cup 304, and are guided into the drain line 306 connected to the waste tank.

As shown in FIG. 7, the track cup 300 has one drain cup 304 and one drain line 306. If the resist material and developer are different based chemicals, more track cups and therefore more tracks (tools) are needed. For example, a water based top anti-reflectance coating (TARC) resist is applied to the top of the resist film 204 deposited on the substrate 202 for reducing a light diffraction at the top of the resist film 204 and improving the resist pattern profile, and most of the resists are organic solvent based chemicals. If the water based TARC resist and the organic based resist are applied at the same coating cup, the water based waste and the organic solvent based waste may gel or precipitate to clog the drain line 300 or the waste tank. Therefore the TARC resist and the organic solvent based resist are used at two separate drain cups or two separate tools, so that the water based waste and the organic solvent based waste are collected into two different cup systems and drain systems to avoid gel or precipitation in the drain line or the waste tank. An extra cup, coater chamber, tool and a clean room footprint are required, and therefore a cost for fabricating the IC devices is increase. In another example, the alcohol solvent base immersion topcoat resist is applied to the top of the resist film 204 deposited on the substrate 202 for reducing a light diffraction at the top of the resist film 204 and reduce the interaction between water and resist during immersion exposure process. The topcoat resist also need separate coating cup from resist coating cup to avoid gel or precipitation in the cup, drain line or the waste tank system. In another example of developing process, a tetramethylammonium hydroxide (TMAH) aqueous developer is used as a positive tone developer (PTD) and an organic solvent developer is used as a negative tone developer (NTD). If the positive tone developer (PTD) and the negative tone developer (NTD) are applied at the same track cup, the water based waste and the organic solvent based waste may gel or precipitate to clog the drain line or the waste tank. Therefore the positive tone developer (PTD) and the negative tone developer (NTP) are used at two separate developing cups or two separate tools, so that the water based waste and the organic solvent based waste are collected into two different drain systems to avoid gel or precipitation in the drain line or the waste tank. An extra developer chamber, tool and a clean room footprint are required, and therefore a cost for fabricating the IC devices is also increase.

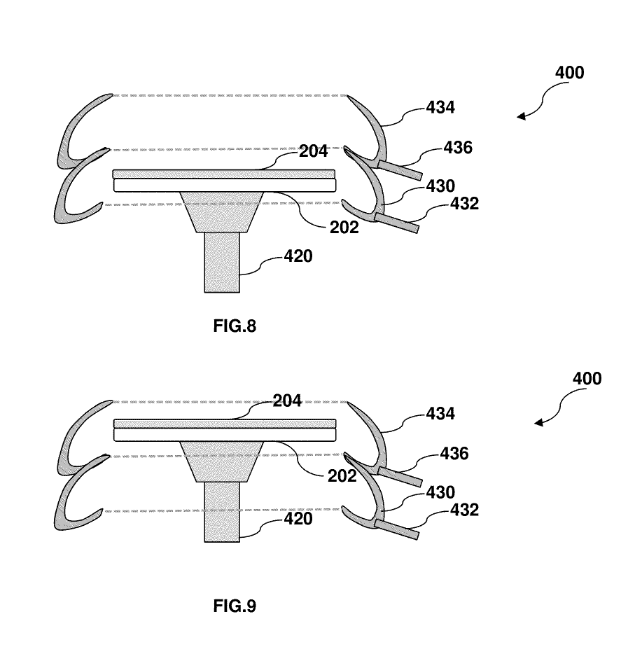

Referring now to FIGS. 8-9, diagrammatic cross-sectional side views of an apparatus 400 is illustrated for implementing one or more embodiments of the present disclosure. The apparatus 400 includes a chuck 420, a first drain cup 430, a first drain line 432, a second drain cup 434, and a second drain line 436. The apparatus 400 is connected to a vacuum system, a liquid delivery system, a rotation system, a wafer transfer system, a wafer loading/unloading system, an exhaust system, and a waste drain system. However, other configurations and inclusion or omission of devices may be possible. In the present disclosure, the apparatus 400 is also referred to as a track cup 400. The apparatus 400 is configured to provide a working environment for depositing a resist film and developing an exposed resist film. For example, the apparatus 400 provides a working environment for depositing and developing the resist film 204 as described with reference to FIGS. 1-6. The chuck 420 is located at the center of the first drain cup 430 and the second drain cup 434. The chuck 420 secures the substrate 202 by the vacuum system when depositing the resist film 204 on the substrate 202 or developing the exposed resist film 204 deposited on the substrate 202. The first drain cup 430 is integrated with the exhaust system at a bottom of the drain cup 430. The first drain line 432 is coupled to the bottom of the first drain cup 430. The second drain cup 434 is located above the first drain cup 430 and is integrated with the first drain cup 430 at the bottom of the drain cup 430. The second drain line 436 is coupled to the bottom of the second cup 434.

Continuing with the present embodiment, a position of the chuck 420 is adjusted inside the first drain cup 430 and the second drain cup 434. When the chuck 420 is positioned in the first drain cup 430 as shown in FIG. 8, depositing the resist film 204 or developing the exposed resist film 204 are performed at the first drain cup 430 with similar polarity property. Therefore, chemical waste with similar polarity can be collected into the first drain line 432. When the chuck 302 is in high position as shown in FIG. 9, depositing the resist film and developing the exposed resist film are performed at the second drain cup 434 with similar polarity property. Therefore the chemical waste with similar polarity can be collected into the second drain line 432. Thus two different chemical based resists or developers may be used at the same track cup 400 to save the coating or developer chamber, tools and clean room footprint and furthermore the cost. For example, the organic solvent based resist is applied in the first drain cup 430 when the chuck 302 is in the low position as shown in FIG. 8. Therefore, the organic solvent based waste is collected into the first drain line 432 connected to an organic solvent based waste tank. In another example, water based TARC resist or immersion topcoat is applied in the second drain cup 434 when the chuck 302 is in the high position as shown in FIG. 9. Therefore, the water based waste is collected into the second drain line 436 connected to a water based waste tank. In another embodiment, the organic solvent based developer is applied in the first drain cup 430 when the chuck 302 is in the low position as shown in FIG. 8. Therefore, the organic solvent based waste is collected into the first drain line 432 connected to an organic solvent based waste tank. In another example, water based TMAH developer is applied in the second drain cup 434 when the chuck 302 is in the high position as shown in FIG. 9. Therefore, the water based waste is collected into the second drain line 436 connected to a water based waste tank. Accordingly, both the organic solvent based resist and the water based resist can be used at the same track cup chamber, and both the organic solvent based developer and the water based developer can also used the same track cup chamber. Therefore, the tool and the clean room space are saved.

Thus, the present disclosure describes a unique apparatus, such as a track cup with two drain cups. In one embodiment, the apparatus includes a chuck, a first drain cup, a second drain cup, a first drain line, and a second drain line. The chuck position is adjustable. Both drain cups are circle and round the chuck. The first drain line is connected to the bottom of the first drain cup and the second drain line is connected to the bottom of the second drain cup. The second drain cup is integrated with the first drain cup and is located on top of the first cup.

The present disclosure also describes an application for the unique apparatus with two drain cups. In one embodiment, when the chuck is in low position, a water based chemical waste is collected into the first drain line. In another embodiment, when the chuck is in high position, an organic solvent based chemical waste is collected into the second drain line. Therefore, two different based chemicals can be used at the same track cup to save tool and clean room space and furthermore the cost.

In another embodiment, a method of forming a resist pattern by using the unique apparatus with two drain cups includes depositing a resist film on a substrate at the same track cup with two drain cups. The method further includes developing the exposed resist film by using a water based developer or an organic solvent developer at the same track cup with two drain cups.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. An apparatus, the apparatus comprising:
a chuck configured to secure a substrate;
a first drain cup within which the chuck is configured to operate when a first based chemical is being dispensed;
a second drain cup integrated with the first drain cup, wherein the second drain cup is configured for the chuck to operate when a second based chemical is being dispensed;
a first drain line coupled with the first drain cup for collecting a first based chemical waste derived from the first based chemical; and
a second drain line coupled with the second drain cup for collecting a second based chemical waste derived from the second based chemical.

2. The apparatus of claim 1, wherein the chuck operates in the first drain cup and the second drain cup.

3. The apparatus of claim 1, wherein the first based chemical is different than the second based chemical.

4. The apparatus of claim 3, wherein the difference between the first based chemical and the second based chemical is a physical phase difference.

5. The apparatus of claim 4, wherein the first based chemical and the second based chemical cannot dissolve each other.

6. The apparatus of claim 1, wherein the first based chemical waste is collected into the first drain line when the chuck operates in the first drain cup.

7. The apparatus of claim 1, wherein the second based chemical waste is collected into the second drain line when the chuck operates in the second drain cup.

8-20. (canceled)

21. An apparatus comprising a track cup including a chuck, a drain cup, and a drain line;
wherein the track cup is connectable to a liquid deliver system and a rotation system;
wherein the track cup is configured for providing a resist material onto a wafer.

22. The apparatus of claim 21, wherein the resist material is provided through the liquid delivery system.

23. The apparatus of claim 21, wherein the drain cup exhausts through the drain line such that to remove excess resist material from the wafer.

24. The apparatus of claim 21, wherein the track cup is also configured for providing a developing solution on the wafer

25. The apparatus of claim 21, wherein the track cup is connectable to a vacuum system,

26. The apparatus of claim 21, wherein the track cup is connectable to a wafer transfer system
